(19) United States
(12) Patent Application Publication
(10) Pub. No.: US 2013/0170667 A1
(43) Pub. Date: Jul. 4, 2013

(54) CLOCK REGENERATION CIRCUIT AND DIGITAL AUDIO REPRODUCTION DEVICE

(71) Applicant: Shinetsu KATOU, Osaka (JP)

(72) Inventor: Shinetsu KATOU, Osaka (JP)

(73) Assignee: PANASONIC CORPORATION, Osaka (JP)

(21) Appl. No.: 13/608,429

(22) Filed: Sep. 10, 2012

(30) Foreign Application Priority Data
Dec. 28, 2011 (JP) 2011-288450

(51) Int. Cl. H03G 5/00

(52) U.S. Cl. 381/98

(57) ABSTRACT

A frequency detection circuit of a clock regeneration circuit measures time which an input clock takes to change a predetermined number of times, and outputs a count value proportional to the time. A division ratio generation circuit truncates bits of the output of the frequency detection circuit by using a quantizer, and outputs the obtained value as a division ratio. A variable frequency divider divides a master clock by the division ratio output from the division ratio generation circuit, and outputs the obtained clock as a new clock. A high-quality clock having reduced jitter is regenerated, so that audio reproduction with high-quality sound is possible.

### CROSS-REFERENCE TO RELATED APPLICATION

This application claims priority to Japanese Patent Application No. 2011-288450 filed on Dec. 28, 2011, the disclosure of which including the specification, the drawings, and the claims is hereby incorporated by reference in its entirety.

### BACKGROUND

The present disclosure relates to digital audio reproduction devices, and specifically to a digital audio reproduction device having increased accuracy of time information in the case of transmitting an digital audio signal to enhance sound quality.

In recent years, merging audio functions with video functions has advanced, and CDs, which had been played on devices fabricated exclusively for audio reproduction, have often been played on video devices such as DVD players and BD players. Under present circumstances, people who try to enjoy music with enhanced sound quality mention that quality of sound reproduced by the video devices is lower than that of the sound reproduced by the audio devices. This is because the video devices are provided with functions unnecessary for the audio reproduction, and thus the sound is susceptible to noise, or because the sound is influenced by cost reduction of the video devices. However, in practice, there are more fundamental problems as described below.

When audio CDs are played on video devices, a clock of 44.1 kHz, which is a sampling frequency of the CDs, is generated from a video operation clock of 27 MHz. Document 1 (PCM1723 datasheet, Texas Instruments Inc.) describes an example of a D/A converter including such a clock generation circuit.

FIG. 8 is a block diagram illustrating a conventional digital audio reproduction device having such a clock system. A high-quality-clock generation circuit 10 of a digital audio reproduction device 50 of FIG. 8 includes a crystal oscillator, and generates a high-quality operation clock of 27 MHz. A phase lock loop circuit (PLL circuit) 11 generates a 44.1 kHz-system clock from the operation clock. A signal processing circuit 12 is operated by the clock generated by the PLL circuit 11, and a D/A converter 13 converts an output of the signal processing circuit 12 to an analog signal.

In the PLL circuit 11, as described in Document 1, phase comparison between a reference clock and an output clock is performed, and an obtained phase error signal is output through a low-pass filter (LPF) to a voltage-controlled oscillator (VCO) to perform feedback control so that a phase error between an output of the VCO and the reference clock is small. Specifically, the phase comparison is performed between a signal obtained by dividing a 27 MHz reference clock by 125 and a signal obtained by dividing the output clock by 784, thereby obtaining a frequency of 169.344 MHz as an output frequency of the VCO, and the obtained output frequency is divided by 15 to generate a clock of 11.2896 MHz, which is 256 times 44.1 kHz.

Based on the 11.2896 MHz clock, the signal processing circuit 12 generates a 44.1 kHz sampling clock, and a transfer clock having a frequency which is 64 times the frequency of the sampling clock, and outputs the generated clocks together with data to the D/A converter 13.

### SUMMARY

As described above, in the conventional configuration, frequency relationship in generating clocks is not expressed by a simple ratio, and thus a complex clock generation circuit is required, so that the generated clocks may have subtle variability over time (jitter) due to the influence of a phase comparison error, noise of the VCO, etc.

When the D/A converter 13 converts digital data to an analog signal by using PLL clocks including such jitter and thus having reduced quality, sound quality may be reduced by the influence of the jitter.

In the present disclosure, a high-quality clock with reduced jitter is regenerated, and the clock is used to allow audio to be reproduced with high-quality sound.

In one aspect of the present disclosure, a clock regeneration circuit for generating a new clock from an input clock includes: a frequency detection circuit configured to measure time which the input clock takes to change a predetermined number of times, and output a count value proportional to the time as an N-bit digital signal, where N is an integer equal to or greater than 2; a division ratio generation circuit including a quantizer and configured to truncate the N-bit digital signal to M bits, where M is an integer less than N, by the quantizer and output the truncated signal as a division ratio; and a variable frequency divider configured to divide a master clock by the division ratio, and output the divided clock as the new clock.

With this configuration, the frequency detection circuit outputs a count value as an N-bit digital signal, where the count value is proportional to time which an input clock takes to change a predetermined number of times. The division ratio generation circuit truncates the N-bit digital signal to M bits to generate a division ratio. The variable frequency divider divides a master clock by the division ratio to obtain a new clock. That is, variable frequency division of the master clock is performed based on frequency information of the input clock to generate the new clock. Thus, while the high quality of the master clock is maintained, an output clock converted to a preferred frequency can be regenerated.

In another aspect of the present disclosure, a digital audio reproduction device includes: the above-described clock regeneration circuit; and an asynchronous sampling rate converter configured to receive audio data and the new clock output from the clock regeneration circuit, convert a sampling rate of the audio data, and output the converted data at a predetermined output frequency.

With this configuration, the asynchronous sampling rate comparator has a function of reducing high-frequency jitter. Thus, even when the clock regenerated by the variable frequency divider includes high-frequency jitter, the influence of the jitter can be removed. Thus, it is possible to obtain a high-quality audio output with reduced influence of the jitter.

According to the present disclosure, it is possible to regenerate a high-quality clock with jitter being reduced by variable frequency division. Thus, without using a PLL, it is possible to obtain a high-quality audio output with reduced influence of the jitter in an overall bandwidth only by a digital circuit.

### BRIEF DESCRIPTION OF THE DRAWINGS

FIG. 1 is a block diagram illustrating a digital audio reproduction device including a clock regeneration circuit according to a first embodiment.

FIG. 2 is a view illustrating an example configuration of a division ratio generation circuit having a noise shaping function.

FIG. 3 is a graph illustrating an example of output values of the circuit of FIG. 2.

FIG. 4 is a block diagram illustrating a digital audio reproduction device including a clock regeneration circuit according to a second embodiment.

FIG. 5 is a block diagram illustrating a digital audio reproduction device including a clock regeneration circuit according to a third embodiment.

FIG. 6 is a block diagram illustrating a digital audio reproduction device including a clock regeneration circuit according to a fourth embodiment.

FIG. 7 is a block diagram illustrating a signal transceiver including a clock regeneration circuit according to a fifth embodiment.

FIG. 8 is a block diagram illustrating a conventional digital audio reproduction device.

### DETAILED DESCRIPTION

### First Embodiment

FIG. 1 is a block diagram illustrating a main configuration of a digital audio reproduction device including a clock regeneration circuit according to a first embodiment. In FIG. 1, a digital audio reproduction device 1 includes a clock regeneration circuit 104 configured to generate an output clock CK2 serving as a new clock from an input clock CK1, an asynchronous sampling rate converter (ASRC) 107 configured to convert a sampling rate of audio data, and a D/A converter 13 configured to convert an output of the ASRC 107 to an analog signal. The input clock CK1 of FIG. 1 is, for example, a clock output from the signal processing circuit 12 of FIG. 8.

The clock regeneration circuit 104 includes a master clock generation circuit 100 configured to generate a high-quality master clock including low jitter, a frequency detection circuit 101 configured to output a count value corresponding to time which the input clock CK1 takes to change a predetermined number of times, a division ratio generation circuit 102 configured to determine a division ratio of the master clock based on the output of the frequency detection circuit 101, and a variable frequency divider 103 configured to divide the master clock by the division ratio determined in the division ratio generation circuit 102. An output of the variable frequency divider 103 is fed to the ASRC 107 as the output clock CK2.

A configuration and operation of the clock regeneration circuit 104 will be specifically described.

The frequency detection circuit 101 measures time required for an input clock CK1 to change a predetermined number of times (which is referred to as “detection time constant”) by using, for example, a master clock. The frequency detection circuit 101 outputs a count value proportional to the time as an N-bit digital signal, where N is an integer equal to or greater than 2. That is, the count value output from the frequency detection circuit 101 is smaller, when the frequency of the input clock CK1 is higher, whereas the count value is larger, when the frequency of the input clock CK1 is lower. The division ratio generation circuit 102 includes a quantizer, truncates the N-bit digital signal output from the frequency detection circuit 101 to M bits, where M is an integer less than N, by the quantizer, and outputs the obtained signal as a division ratio.

Here, it is assumed that the frequency of the master clock is 98.304 MHz, and the clock regeneration circuit 104 generates an output clock CK2 having a frequency which is 128 times the frequency of the input clock CK1. The frequency detection circuit 101 measures, for example, time which the input clock CK1 takes to change 16384 times. The case where the frequency of the input clock CK1 is 48 kHz is regarded as a reference. When the measured time is the standard time of the case of 48 kHz, the frequency detection circuit 101 outputs a count value of “16384.” When the frequency of the input clock CK1 changes, the frequency detection circuit 101 outputs a value proportional to the measured time. For example, in the case of 44.1 kHz, the count value is slightly higher, and the frequency detection circuit 101 outputs a count value of “17833” (=16384×48/44.1).

In this case, the frequency of the output clock CK2 is 44.1 kHz×128=5.6448 MHz, and a division ratio for the master clock is a value of “17.41 . . . ” The value “17.41 . . . ” multiplied by 1024 is “17833,” which can be associated with the output of the frequency detection circuit 101.

The noninteger division ratio “17.41 . . . ” can be obtained by combining two types of division ratios, that is, “17” and “18.” For example, when “17” and “18” are alternately used, a division ratio of “17.5” is obtained. Thus, to obtain the division ratio “17.41 . . . ,” a combination in which the rate of “17” is slightly larger than that of “18” may be used. An integerization process as described above has been widely used in the field of digital audio as quantization. Note that since a quantization error occurs, the division ratio generation circuit 102 of the present embodiment has a so-called noise shaping function to reduce the influence of the quantization error.

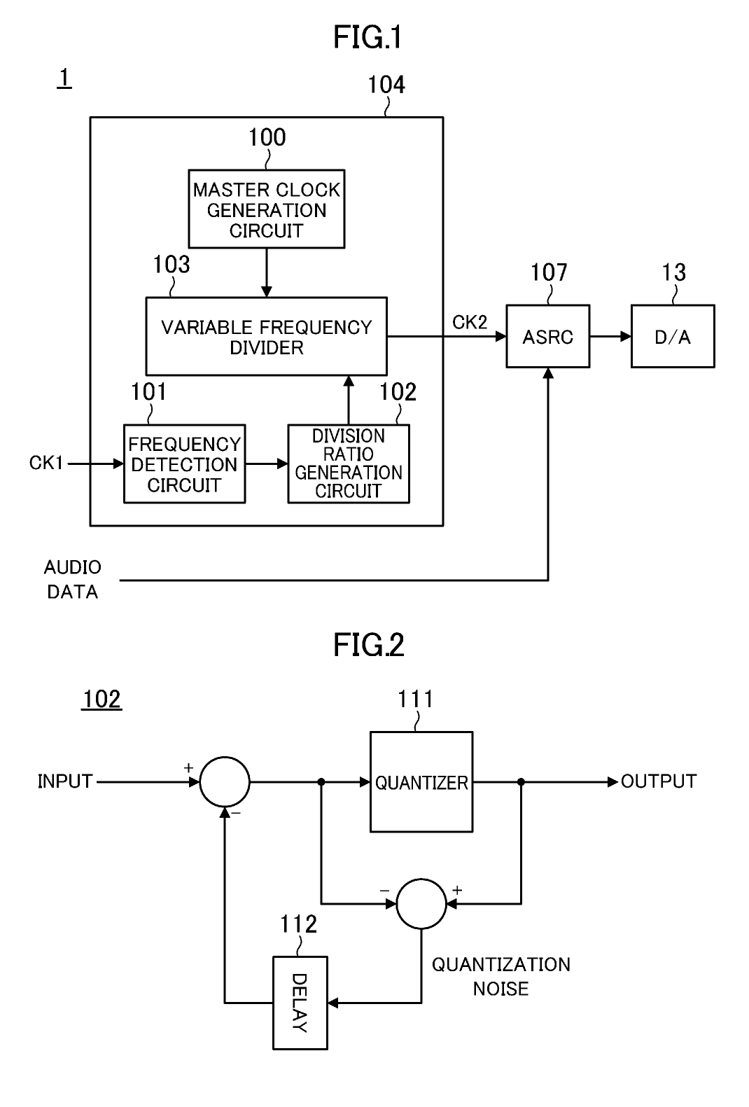

FIG. 2 illustrates an example configuration of the division ratio generation circuit having a primary noise shaping function. In FIG. 2, a quantizer 111 truncates an N-bit digital signal (e.g., a 16-bit digital signal) to M bits (e.g., 5 bits), thereby performing the process of reducing the number of bits of an output data. Then, an input of the quantizer 111 is subtracted from an output of the quantizer 111 to compute an error caused by the quantization, that is, quantization noise, and the quantization noise is fed back to an input side via a delay circuit 112.

From FIG. 2, it can be seen that the following expression holds true:

Output=Input+(1−Z)Vq

where Vq is the quantization noise, and Z is the delay process.

Here, (1−Z) means that a difference between data of current time and data of time immediately before the current time is computed, which is the same as the definition of the differential. Thus, an output of the circuit of FIG. 2 results from adding a signal obtained by differentiating the quantization noise to an input signal. In terms of the quantization noise, this does not simply mean the occurrence of the quantization noise, but means the occurrence of noise changed into a differential form. For this reason, the circuit as illustrated in FIG. 2 is referred to as a circuit for changing the shape of noise, that is, a noise shaping circuit. A noise shaping process by the differential provides the circuit of FIG. 2 with properties that low-frequency components in noise decrease, whereas high-frequency components increase. That is, the smaller a variation between a previous data value and a current data value is, the lower the level of the quantization noise added to the output is. As a result, it is possible to obtain an advantage similar to an advantage that accuracy of output data increases. In the present embodiment, the output of the frequency detection circuit 101 generally exhibits almost no variation, so that a noise reduction effect by the noise shaping process is enhanced.

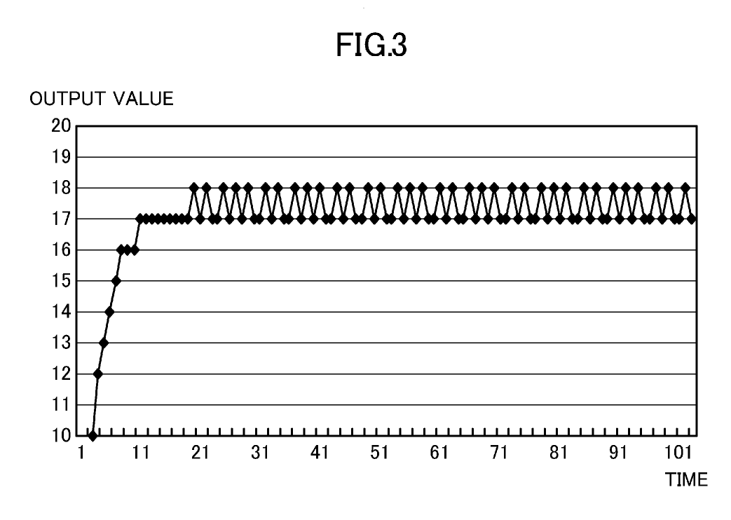

FIG. 3 is a graph illustrating an example of output values of the division ratio generation circuit 102 of FIG. 2. In FIG. 3, it is assumed that the division ratio generation circuit 102 of FIG. 2 receives a 16-bit signal “17833” as an input, and outputs a 5-bit signal. As seen from FIG. 3, after initial responses, “17” and “18” are substantially alternately output, where “17” is output at a slightly higher rate than “18” so that an average value of the outputs is “17.41 . . . .”

Referring back to FIG. 1, the variable frequency divider 103 receives the output value of the division ratio generation circuit 102, divides the master clock output from the master clock generation circuit 100 by using the output value as a division ratio, and outputs the obtained clock. In the present embodiment, the variable frequency divider 103 divides a master clock having a frequency of 98.304 MHz by “17” or “18,” which is the output value of the division ratio generation circuit 102, and outputs a signal having an average frequency of 5.6448 MHz as the output clock CK2.

Here, the output clock CK2 output from the variable frequency divider 103 is a signal obtained by only dividing the high-quality master clock output from the master clock generation circuit 100, and thus the clock itself does not vary unlike a clock generated in a PLL. Only components varying at a high speed due to the noise shaping process are transferred as clock jitter.

The ASRC 107 converts a sampling rate of audio data by using the output clock CK2 of the variable frequency divider 103. The output clock CK2 of the variable frequency divider 103 includes large jitter at a high frequency, but the ASRC 107 has a high-frequency jitter reducing function, and thus output audio data is generated with its jitter reduced by the ASRC 107. The D/A converter 13 converts the audio data output from the ASRC 107 to an analog signal, and outputs the analog signal. The audio data which is generated by the ASRC 107 and has reduced influence of the jitter is converted to the analog signal, and the analog signal is output, so that a high-quality audio signal output can be obtained.

As described above, when a clock is regenerated on a receiver side, jitter which a device on a transmitter side has can be reduced on the receiver side. Thus, for example, even when a CD is played on a video device, it is possible to obtain an audio signal with high-quality sound.

As can be seen from the example described above, a clock output of the clock regeneration circuit 104 includes high-speed variations due to properties of the noise shaping function. However, the range of the variations is equivalent to that of only one master clock, and thus is about 1/35 of the range of the variation of a transfer clock which is 64 times the sampling frequency. Thus, transfer data is determined by extracting the transfer data on the transfer clock, so that no problem arises.

Note that specific values of the number of counts of the input clock, the number of processed bits, the frequency of the master clock, etc. described in the embodiment are mere design examples, and can accordingly be changed.

While a noise shaping circuit has been used as the division ratio generation circuit 102, the present disclosure is not limited to this embodiment, but other algorithm may be used to integerize the division ratio. Moreover, a configuration of the noise shaping circuit is not limited to the circuit configuration of FIG. 2, but, for example, a secondary or higher order noise shaping circuit may be used.

### Second Embodiment

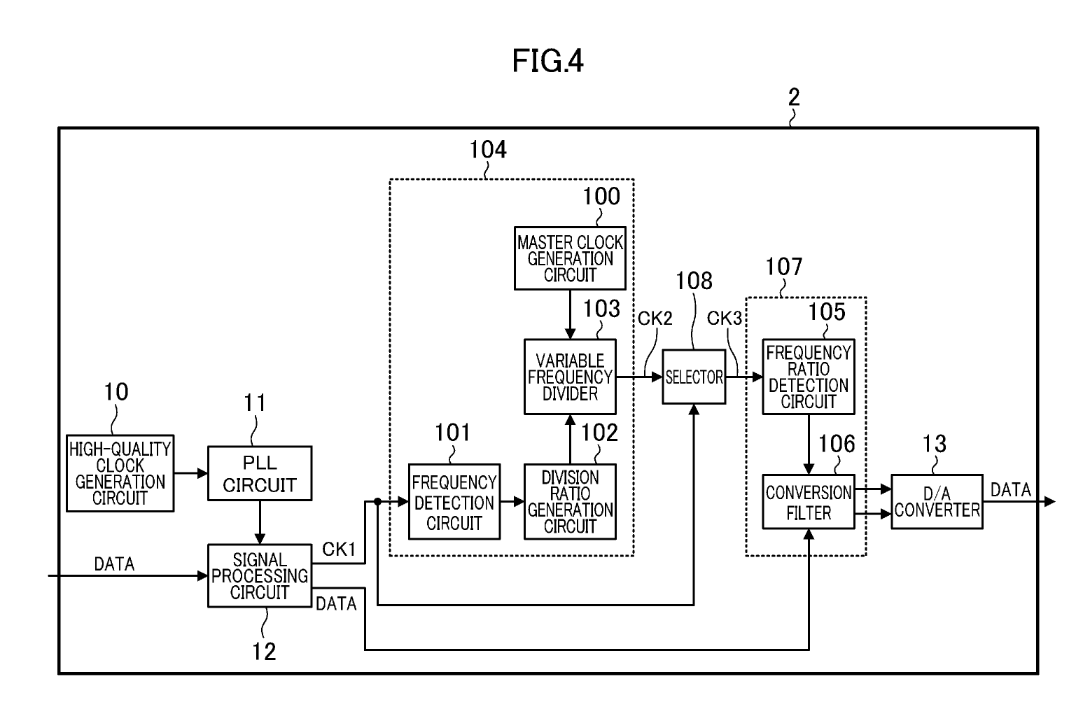

FIG. 4 is a block diagram of a digital audio reproduction device according to a second embodiment. Similar to the configuration of FIG. 1, a digital audio reproduction device 2 of FIG. 4 includes a clock regeneration circuit 104 configured to generate an output clock CK2 from an input clock CK1, an ASRC 107 configured to convert a sampling rate of audio data, and a D/A converter 13 configured to convert an output of the ASRC 107 to an analog signal. Moreover, the high-quality-clock generation circuit 10, the PLL circuit 11, and the signal processing circuit 12 of FIG. 8 are also illustrated in FIG. 4.

Similar to the configuration of FIG. 1, the clock regeneration circuit 104 includes a master clock generation circuit 100, a frequency detection circuit 101, a division ratio generation circuit 102, and a variable frequency divider 103, and operates in a manner as described in the first embodiment.

Moreover, the ASRC 107 includes a frequency ratio detection circuit 105 configured to measure the ratio of a frequency of an input clock to a predetermined output frequency, and a conversion filter 106 configured to perform an interpolating operation of input data to compute output data. For example, the frequency ratio detection circuit 105 counts an input clock for predetermined time determined by a predetermined output frequency (which is referred to as “measured time constant”), and based on the count value, the frequency ratio detection circuit 105 computes the ratio of the frequency of the input clock to the predetermined output frequency. Thus, no response is made to a frequency variation in a cycle shorter than the measured time constant, so that it is possible to obtain the effect of reducing high-frequency jitter. Based on frequency ratio information computed by the frequency ratio detection circuit 105, the conversion filter 106 performs an interpolating operation of input data to compute output data at the predetermined output frequency. Then, the conversion filter 106 outputs the obtained data at the predetermined output frequency, thereby converting a sampling rate in the ASRC 107.

The digital audio reproduction device 2 of FIG. 4 further includes a selector 108 between the clock regeneration circuit 104 and the ASRC 107. The selector 108 receives the input clock CK1 and the clock CK2 output from the clock regeneration circuit 104, and outputs any one of the clocks CK1, CK2 as a selected clock CK3. The ASRC 107 receives the selected clock CK3 output from the selector 108 instead of the clock CK2 output from the clock regeneration circuit 104.

In the configuration of the present embodiment, response time can be shortened for example, when an input frequency is changed. Here, the influence of time required for the clock regeneration circuit 104 and the ASRC 107 to perform frequency measurement on high-speed responsiveness will be described.

For example, when the frequency of the input clock CK1 is 3.072 MHz which is 64 times 48 kHz, this signal takes about 5.3 ms to change, for example, 16384 times. That is, such an amount of time is required for single measurement in the frequency detection circuit 101. When the frequency in this state changes to, for example, 44.1 kHz, time which is two to three times the above-mentioned amount of time is required to obtain a normal output by detecting a new count value and checking the count value. The same applies to the frequency ratio detection circuit 105.

Such transient response time is required for the frequency measurement in the clock regeneration circuit 104 and the frequency measurement in the ASRC 107. Thus, when a clock whose frequency has changed is sequentially transferred, as in the case where the input clock CK1 is input to the clock regeneration circuit 104, and the output clock CK2 of the clock regeneration circuit 104 is input to the ASRC 107, total response time is significantly long, and is for example, about several ten milliseconds.

In a normal operating state, that is, as long as the frequency of the input clock does not change, such time required for the frequency measurement does not become a problem.

However, for example, when the frequency of the input signal changes, it is not preferable that the response time be about several ten milliseconds, and in some cases, shorter response time is required.

On the other hand, frequency detection (operation of the frequency ratio detection circuit 105) and output data generation (operation of the conversion filter 106) in the ASRC 107 can be concurrently executed as independent processes. Moreover, the input clock CK1 and the output clock CK2 of the clock regeneration circuit 104 differ from each other only in jitter component, but have substantially the same frequency.

Thus, in the present embodiment, when high-speed response is required, the selector 108 outputs the input clock CK1 as the selected clock CK3 instead of the output clock CK2 of the clock regeneration circuit 104. With this configuration, operation of the ASRC 107 is no longer influenced by response time in the clock regeneration circuit 104, and thus response speed can be increased. That is, immediately after switching the selector 108, the conversion filter 106 is operated by the clock CK2 of the clock regeneration circuit 104, while the frequency ratio detection circuit 105 computes a frequency ratio from the input clock CK1 in the ASRC 107.

Note that in the frequency ratio detection circuit 105, a value obtained as the frequency ratio in the case of inputting the input clock CK1 and a value obtained as the frequency ratio in the case of inputting the output clock CK2 of the clock regeneration circuit 104 are substantially the same. However, the input clock CK1 differs from the output clock CK2 in jitter component, and the slight difference significantly influences sound quality. Thus, in a stable operating state, the output clock CK2 of the clock regeneration circuit 104 is preferably selected by the selector 108.

That is, in the normal operating state, the selector 108 outputs the output clock CK2 of the clock regeneration circuit 104 as the selected clock CK3. That is, the output clock CK2 of the variable frequency divider 103 which has jitter shifted to a high frequency is passed through the selector 108, and is input to the ASRC 107.

Selection control of the selector 108 may be performed by, for example, a switching signal from the outside of the digital audio reproduction device. Alternatively, for example, an output of the frequency detection circuit 101 of the clock regeneration circuit 104 is monitored, and when the value of the output exceeds a predetermined range, a need of high-speed response is recognized, and the selector 108 may be switched.

As described above, according to the present embodiment, the selector 108 which is capable of switching clocks input to the ASRC 107 is provided, so that response time can be shortened, for example, when the input frequency changes.

### Third Embodiment

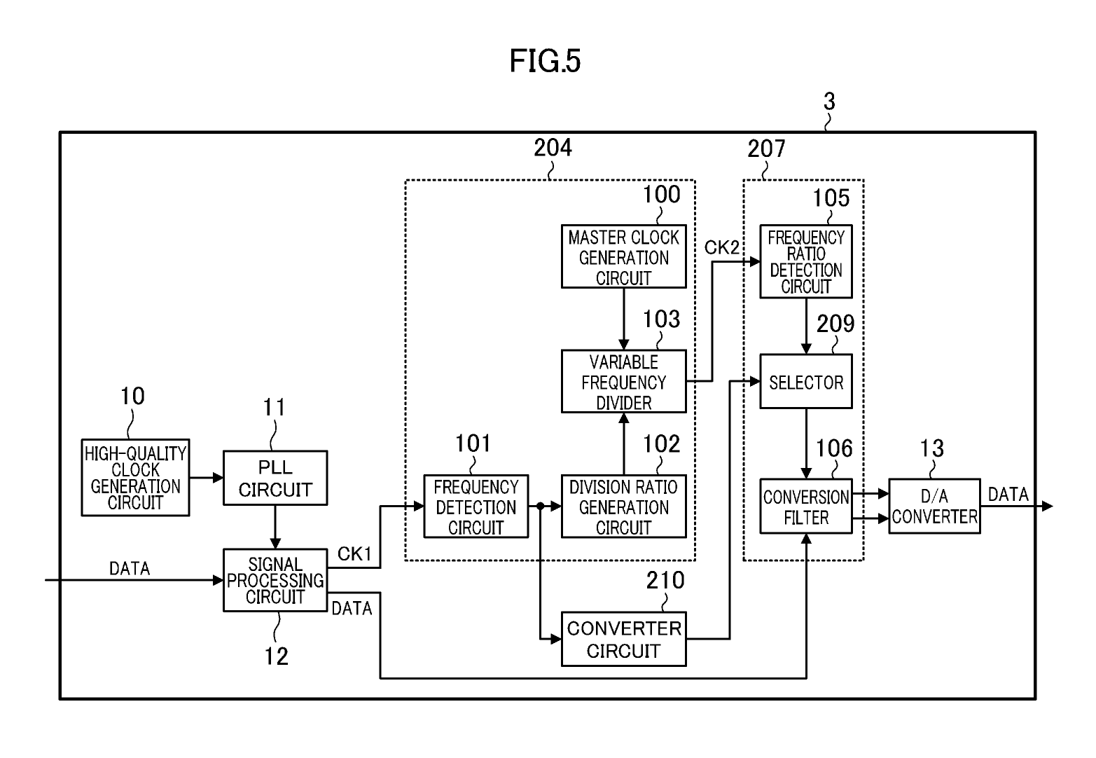

FIG. 5 is a block diagram of a digital audio reproduction device according to a third embodiment. In FIG. 5, the components common with those in FIG. 4 are denoted by the same reference symbols, and detailed description thereof is omitted.

In a digital audio reproduction device 3 of FIG. 5, a clock regeneration circuit 204 has a configuration similar to that of the clock regeneration circuit 104 of FIG. 4, but an output of a frequency detection circuit 101 is output to the outside of the clock regeneration circuit 204. Moreover, an ASRC 207 has a configuration similar to that of the ASRC 107 of FIG. 4, but a selector 209 is provided between a frequency ratio detection circuit 105 and a conversion filter 106. A converter circuit 210 receives the output of the frequency detection circuit 101, that is, a digital signal representing a count value of an input clock CK1, and performs the operation of computing a conversion ratio for use in the ASRC 207 from the digital signal. As frequency ratio information input to the conversion filter 106, the selector 209 of the ASRC 207 selects an output of the frequency ratio detection circuit 105 or the conversion ratio output from the converter circuit 210, and outputs the selected information to the conversion filter 106. That is, the ASRC 207 is capable of switching between the mode of obtaining a conversion ratio from an output clock CK2 of the clock regeneration circuit 204 and the mode of using the conversion ratio received from the converter circuit 210.

The frequency detection circuit 101 in the clock regeneration circuit 204 outputs the count value of the input clock CK1 without processing, whereas the frequency ratio detection circuit 105 in the ASRC 207 computes the ratio of a frequency of the clock CK2 to an output frequency. Thus, the frequency detection circuit 101 and the frequency ratio detection circuit 105 are formed as separate circuits. Therefore, as in the present embodiment, adding the converter circuit 210 performing an operation of a frequency ratio based on the count value of the input clock CK1 allows the clock regeneration circuit 204 and the ASRC 207 to share frequency information. With this configuration, two-step response in the clock regeneration circuit 204 and the ASRC 207 in terms of frequency measurement is no longer necessary, and thus response time can be shortened.

For example, it is assumed that “16384” is obtained as an output value of the frequency detection circuit 101 when the input clock CK1 has a frequency of 48 kHz. In this case, when the frequency changes to 44.1 kHz, the output value becomes “17833.” If the output frequency has been set to 96 kHz, a frequency conversion ratio changes from “2” to “2.1769.” The ratio is obtained by the expression: 17833/16384×2. Thus, although using a circuit performing a multiply and divide operation as the converter circuit 210 is not generally preferred in hardware due to an increasing circuit scale, the circuit performing the multiply and divide operation can compute a necessary conversion ratio.

Selection control of the selector 209 may be performed in a manner similar to the selection control of the selector 108 in the second embodiment. For example, the selector 209 may be controlled so that the output of the frequency ratio detection circuit 105 is selected in a normal state, and the output of the converter circuit 210 is selected when high-speed response is required.

As described above, the present embodiment includes the converter circuit 210 configured to compute the conversion ratio for use in the ASRC 207 from the output of the frequency detection circuit 101, so that response time can be shortened, for example, when the input frequency changes.

### Fourth Embodiment

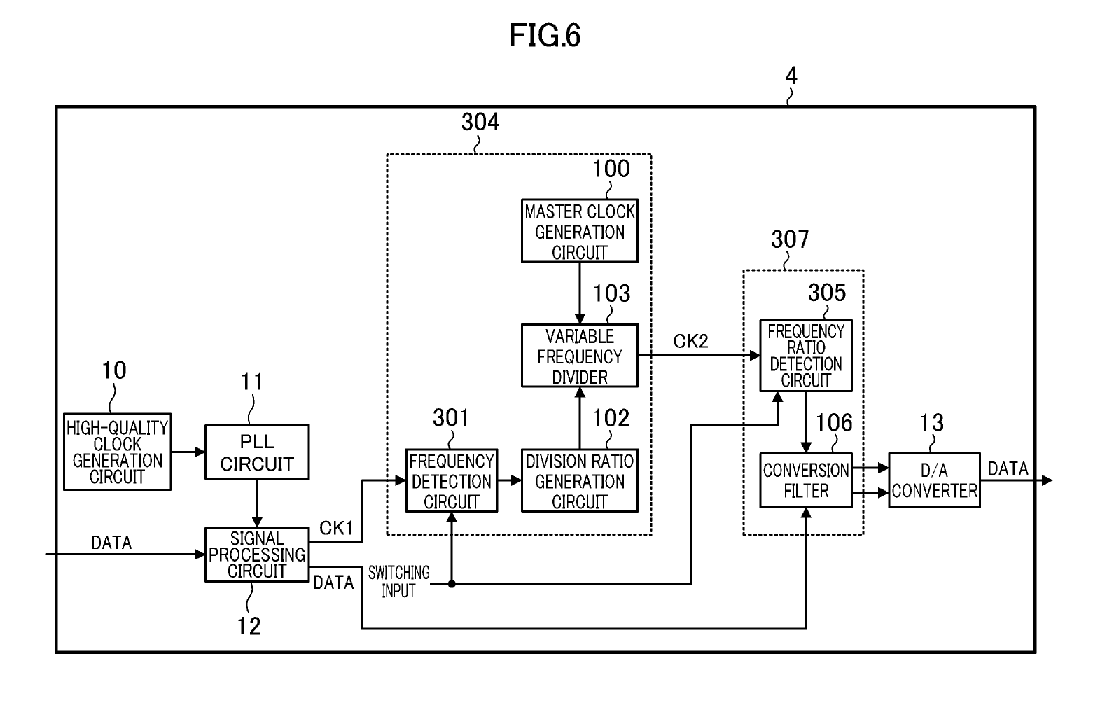

FIG. 6 is a block diagram of a digital audio reproduction device according to a fourth embodiment. In FIG. 6, the components common with those in FIG. 4 or FIG. 5 are denoted by the same reference symbols, and detailed description thereof is omitted.

In a digital audio reproduction device 4 of FIG. 6, a clock regeneration circuit 304 has a configuration similar to that of the clock regeneration circuit 104 of FIG. 4, but a frequency detection circuit 301 is capable of switching a detection time constant for frequency detection, that is, a predetermined number of times that an input clock CK1 is counted. Moreover, an ASRC 307 has a configuration similar to that of the ASRC 107 of FIG. 4, but a frequency ratio detection circuit 305 is capable of switching a measured time constant at frequency ratio measurement, that is, predetermined time which is determined by a predetermined output frequency and during which the clock is counted. Both the frequency detection circuit 301 and the frequency ratio detection circuit 305 externally receive switching inputs to switch the detection time constant or the measured time constant.

In the present embodiment, when the detection time constant or the measured time constant is reduced, response time can be shortened, which allows high-speed response of the digital audio reproduction device 4. For example, in the frequency detection circuit 301, the number of counts is reduced by ¼ to shorten detection time, and a count value multiplied by 4 is output. In this case, the degree of accuracy lowers, but response speed can be increased without changing other processes. Thus, the switching inputs may be controlled so that, for example, a basic time constant is used in a normal state, and the time constant is reduced when high-speed response is required.

In the configuration of FIG. 6, a switching input is input to both the frequency detection circuit 301 and the frequency ratio detection circuit 305. However, individual selection signals may be input to the frequency detection circuit 301 and the frequency ratio detection circuit 305. With this configuration, for example, control can be performed such that only the detection time constant of the frequency detection circuit 301 is reduced, and the frequency ratio detection circuit 305 is allowed to operate normally.

Moreover, the configuration of the present embodiment may be combined with the second or third embodiment.

Alternatively, in each of the embodiments described above, the sampling clock itself can be used as the input clock CK1 input to the clock regeneration circuit instead of a data transfer clock. In this case, for example, when a clock source having high accuracy such as a rubidium oscillator is used, it is possible to further take advantage of the high accuracy. As described above, in general, a clock source having high accuracy outputs a sampling clock, and based on the sampling clock, a PLL, or the like in a signal processing circuit generates a transfer clock having a frequency which is, for example, 64 times the frequency of the sampling clock. Thus, it can be said that the sampling clock is preferably used as an input clock in order to increase the quality of an output clock.

However, in terms of responsiveness, it can be said that the transfer clock, which has a higher frequency than the sampling clock, is preferably used, because response speed can be increased. Thus, for example, different clocks may be used depending on situations, and for example, the sampling clock may used in a stable operating state, and when the input frequency changes, the transfer clock may be used to allow high-speed response. Alternatively, for example, the sampling clock may be used for the clock regeneration circuit, and the transfer clock may be used for the ASRC.

### Fifth Embodiment

The embodiments described above have described the configurations in which the clock regeneration circuit is used in combination with the ASRC having the function of reducing high-frequency jitter. Other than the embodiment described above, the clock regeneration circuit may be applied to, for example, the case where it will suffice to obtain averagely precise frequency, or the case of communicating with the other end in which the high-frequency jitter reducing function is preinstalled. Examples of the latter case include a digital audio interface circuit for transferring data via a single coaxial cable which is generally called IEC958.

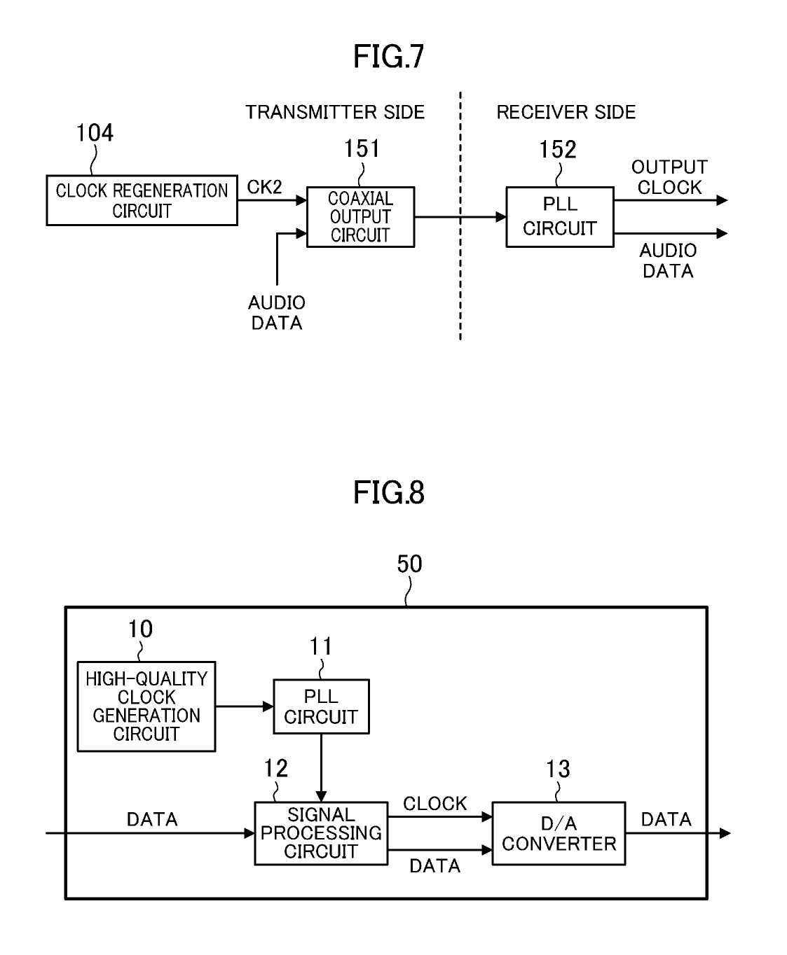

FIG. 7 is a block diagram schematically illustrating a configuration of a transceiver including a clock regeneration circuit according to a fifth embodiment. In the configuration of FIG. 7, an IEC958 signal is sent from a transmitter side to a receiver side. On the transmitter side, a clock regeneration circuit 104 which is similar to that described in the first embodiment, and a coaxial output circuit 151 are provided, and on the receiver side, a PLL circuit 152 is provided.

The coaxial output circuit 151 generates an IEC958-format biphase modulating signal by using audio data and a clock input, and outputs the generated signal to a coaxial cable or an optical cable. Here, a clock CK2 which is generated in the clock regeneration circuit 104, and has high quality but include jitter at a high frequency is used instead of a clock generated in a conventional PLL. The generated biphase modulating signal is transferred via the cable to the receiver side.

On the receiver side, the PLL circuit 152 demodulates biphase modulation and regenerates a clock to extract clock information of the transferred signal. The PLL has the function of reducing high-frequency noise, and thus a clock extracted by the PLL circuit 152 has no influence of the high-frequency jitter, so that a high-quality clock is regenerated. This increases quality of an audio signal reproduced on the receiver side.

Note that when the clock regeneration circuit is used on the transmitter side as in the present embodiment, there is no need to measure the clock information, and thus it is possible to directly set a predetermined division ratio. That is, an output clock having a preferred frequency can be output without using the PLL on the transmitter side.

According to the present disclosure, a high-quality clock can be generated, and thus, for example, the present disclosure is useful for high-quality audio reproduction in digital audio reproduction devices.

What is claimed is:

1. A clock regeneration circuit for generating a new clock from an input clock, the clock regeneration circuit comprising:
a frequency detection circuit configured to measure time which the input clock takes to change a predetermined number of times, and output a count value proportional to the time as an N-bit digital signal, where N is an integer equal to or greater than 2;
a division ratio generation circuit including a quantizer and configured to truncate the N-bit digital signal to M bits, where M is an integer less than N, by the quantizer and output the truncated signal as a division ratio; and
a variable frequency divider configured to divide a master clock by the division ratio, and output the divided clock as the new clock.

2. The clock regeneration circuit of claim 1, wherein
the division ratio generation circuit has a noise shaping function.

3. A digital audio reproduction device comprising:
the clock regeneration circuit of claim 1; and
an asynchronous sampling rate converter configured to receive audio data and the new clock output from the clock regeneration circuit, convert a sampling rate of the audio data, and output the converted data at a predetermined output frequency.

4. The digital audio reproduction device of claim 3, further comprising:
a selector configured to receive the input clock and the new clock output from the clock regeneration circuit, and output the input clock or the new clock as a selected clock, wherein
the asynchronous sampling rate converter receives the selected clock output from the selector instead of the new clock.

5. The digital audio reproduction device of claim 3, further comprising:
a converter circuit configured to compute a conversion ratio for use in the asynchronous sampling rate converter from the N-bit digital signal output from the frequency detection circuit included in the clock regeneration circuit, wherein
the asynchronous sampling rate converter is configured to switch between a mode of computing a conversion ratio from the new clock and a mode of using the conversion ratio received from the converter circuit.

6. The digital audio reproduction device of claim 3, wherein
the frequency detection circuit included in the clock regeneration circuit is configured such that the predetermined number of times is externally changeable.
